(19) United States
(12) Patent Application Publication
(10) Pub. No.: US 2005/0134879 A1
(43) Pub. Date: Jun. 23, 2005

(54) Process for the generation of a color profile for a digital camera

(75) Inventors: Dietmar Fuchs, Munster (DE); Harald Ammeter, Zurich (CH)

Correspondence Address: BURNS DOANE SWECKER & MATHIS L L P, POST OFFICE BOX 1404, ALEXANDRIA, VA, 22313-1404, US

(73) Assignee: Logo Beteiligungsges. mbH

(21) Appl. No.: 10/995,209

(22) Filed: Nov. 24, 2004

(30) Foreign Application Priority Data
Nov. 27, 2003 (EP) 03 027 377.5

(51) Int. Cl. G06F 15/00; G03F 3/08

(52) U.S. Cl. 358/1.9; 358/518; 382/167

(57) ABSTRACT

For the generation of a color profile for a digital camera a user surface is made available which allows for the input or adjustment or selection of reproduction influencing quantities characterizing the transformation behavior of the profile (P) to be generated. From the input or adjusted or selected reproduction influencing quantities, corresponding optimization rules for the optimization of the parameters for the model of the digital camera used for the profile calculation and/or corresponding correction rules for the table values of the profile (P) are determined. The optimization of the parameters of the model of the digital camera is carried out by way of these optimization rules, and the table values of the profile (P) are changed according to these correction rules. The different reproduction influencing quantities are combined to sensible combinations and offered to the user with suitable pre-settings by way of the user surface for selection or individual assessment. The user can thereby carry out in an easy and intuitive manner perception based and individual taste based aspects of the color reproduction as well as influencing measures on the color reproduction known from the classical analog photography, and can let them flow into the profile generation.

### CROSS-REFERENCE TO RELATED APPLICATIONS

This application claims benefit to European Priority Patent Application Ser. No. 03 027 377.5, filed Nov. 27, 2003. This priority application is hereby incorporated by reference in its entirety.

### FIELD OF THE INVENTION

The invention relates to a process for the generation of a color profile for a digital camera using reference data and camera data and a mathematical model of the digital camera defined by variable parameters, whereby the reference data (DR) represent color values of color fields of a color table (FT) in relation to a device independent color space and the camera data (DK) represent color values of the color fields of the color table produced by the digital camera upon capture of the color table in relation to the device specific color space of the digital camera (K), and whereby the model of the digital camera transforms color values relating to the device independent color space into color values of the device specific color space of the digital camera (K), in which process the reference data (DR) are transformed by way of the model (20) of the digital camera into the device specific color space of the digital camera.

### BACKGROUND ART

Color management and color management systems are generally known and are commonly used in digital color reproduction processes. A comprehensive and clear illustration of the background, technologies and applications of color management systems is found in the publication “Postscriptum on Color Management, Philosophy and Technology of Color Management” of the authors Stefan Brües, Liane May and Dietmar Fuchs, published August 1999 by the company Logo GmbH, a company of the Gretag-Macbeth Group. A further discussion of color management is found, for example, in chapter 17 “Device-Independent Color Imaging” of the book “Color Appearance Models” of Mark D. Fairchild, first edition, published 1997 by Addison Wesley.

Color profiles or generally device profiles play a central role in the color management. They serve the specific color value transformation between a device specific color space and a device independent color space. Digital cameras usually deliver RGB-color values as output signals and, correspondingly, the device specific color space of the digital cameras is the RGB-color space. The CIE-Lab-color space is most often used as the device independent color space. Color profiles for digital cameras therefore transform the RGB-color values of the digital camera into corresponding CIE-Lab color values.

Color profiles are with respect to their principal structure normally standardized. A known and generally common standard is the one according to ICC (International Color Consortium) www.color.org, specification according to ICC www.color.org/icc_specs2.html). Color profiles corresponding to this standard are therefore often also called ICC profiles. Device profiles are divided into output device profiles and input device profiles. Output device profiles are used in connection with output devices (printers, screens, beamers, etc.) controlled by color value data, input device profiles correspondingly with color value data producing input devices (scanners, digital cameras, etc.).

The generation (calculation) of color profiles is usually carried out using a color table which includes a representative selection of different color fields, the color values of which in the underlying device independent color space are known (for example by measurement with a calibrated and highly precise color measurement device). For an input color profile, the color table is digitalized by the corresponding input device, which means for each color field, the matching color values are produced in the device color space of the input device. From these two data sets—the color values of the color fields in the device independent color space and the color values in the color fields of the device specific color space—the color profile for the input device is then calculated by mathematical methods, whereby also different standardized reproduction criteria (rendering intents) are taken into consideration. For these reproduction criteria, one distinguishes between the modes “perceptual” (equal color impression in the image), “relative calorimetric”, “absolute calorimetric” and “saturation”, which are defined in the document ICC-1:1998-09 of the ICC (International Color Consortium). For the calculation of the color profile, the software package “Profile Maker Pro” of the above mentioned company Logo GmbH, a company of the Gretag-Macbeth Group, can be used, for example.

Color profiles for digital cameras produced according to these general principles or procedures take into consideration only the purely calorimetric properties and standardized reproduction criteria, but are not sufficient or only in a limited way for the perception based and individual-taste related aspects of color reproduction. Especially professional photographers and advanced amateurs make higher demands in that they want to also use in the digital photography the possibility of influencing the color reproduction known from the analog (classical) photography. These influencing or design possibilities include, for example, the use of different film types and the use of different illumination types during the image capture. A further problem of conventionally produced color profiles lies in the treatment of special colors (spot colors) as well as in frequently occurring undesired color hues with colors close to the gray axis.

### SUMMARY OF THE INVENTION

It is therefore a general goal of the present invention to improve the generation of color profiles for digital cameras in such a way that either the above mentioned higher demands are met, or the above mentioned difficulties with conventional color profiles are overcome, or both. More concretely, the invention in one embodiment is to provide the possibility, for example, to carry out, during profile generation, measures for influencing the color reproduction known from the classical analog photography in a simple and intuitive manner and to let them flow into the profile generation. In another embodiment, the invention is to provide the possibility to specifically take into consideration special colors during a profile generation and preferably to treat especially colors in the vicinity of the gray axis.

This is achieved in accordance with a preferred embodiment of the invention in that a preferably graphic user surface is made available, which allows the input, or adjustment, or selection of reproduction influencing quantities characterizing the transformation behavior of the profile (P) to be generated, that from the input, or adjusted, or selected reproduction influencing quantities corresponding optimization rules for the optimization of the parameters of the model of the digital camera and/or corresponding correction rules for the table values of the profile (P) are determined, and that the optimization of the parameters of the model of the digital camera is carried out by way of the optimization rules and the table values of the profile (P) are changed according to the correction rules.

### BRIEF DESCRIPTION OF THE DRAWINGS

The invention is further described in the following by way of the drawing, wherein:

FIG. 1 is a principal block diagram of an exemplary embodiment of the process in accordance with one embodiment of the invention for the generation of a color profile for a digital camera;

FIG. 2 shows the structure of an ICC-color profile;

FIG. 3 is a principal block diagram of a profile generator with a mathematic model of a digital camera included therein;

FIG. 4 is a block diagram of various steps of the process;

FIGS. 5-8 show exemplary graphs of typical correction functions; and

FIGS. 9-10 show exemplary design possibilities for a graphic user surface.

### DETAILED DESCRIPTION OF THE PREFERRED EMBODIMENTS

The invention is described in the following by way of the example of generating an ICC-color profile, whereby the RGB-color space is used as the device specific color space and the CIE-Lab-color space is used as the device independent color space. The process in accordance with the invention is however not limited thereto, but can be accordingly also used for other color space combinations and color profile types.

The starting point for generation of a color profile according to one embodiment of the invention is a physical color table FT with a representative number of differently colored color fields FF, the color values of which are distributed over the whole color space of interest. Normally, a two dimensional array of color fields is used, but other configurations are also possible. For each color field of the color table, the matching color values in a device independent color space, here thus the CIE-Lab-color space, are known. These color values can be determined, for example, by measurement with a highly precise color measurement device. Normally this is done already by the manufacturer of the color table. The CIE-Lab-color values are practically stored in a digital file. The totality of the CIE-Lab-color values of all color fields of the color table is in the following referred to as reference data DR.

Alternatively, the remission spectra of the color fields of the color table can also be measured or be present instead of the CIE-Lab-color values, whereby the totality of all remission spectra is referred to as spectral measurement data DS. The Lab-color values or reference data DR can be calculated from the spectral measurement data according to the known standards of the CIE (Commission Internationale de I'Eclairage).

Next, an image of the color table FT is taken with the digital camera K, for which a color profile P is to be generated. The camera thereby produces for each captured image point a color value in the device specific color space of the camera, thus here in the RGB-color space. The RGB-color values of the individual color fields FF of the color table FT are extracted from the RGB-color values of all captured image points according to generally known methods. The totality of the RGB-color values of the color fields is in the following referred to as camera data DK.

The profile P is now calculated from the reference data DR and the camera data DK. To date this was done in that the camera data and the reference data were fed directly or after a chromatic adaptation to a commercially available profile generator PG, which calculated the profile P therefrom and stored it in the standardized ICC-format. A suited profile generator is, for example, included in the software packet “Profile Maker Pro” of the above mentioned company Logo GmbH, a company of the Gretag-Macbeth Group.

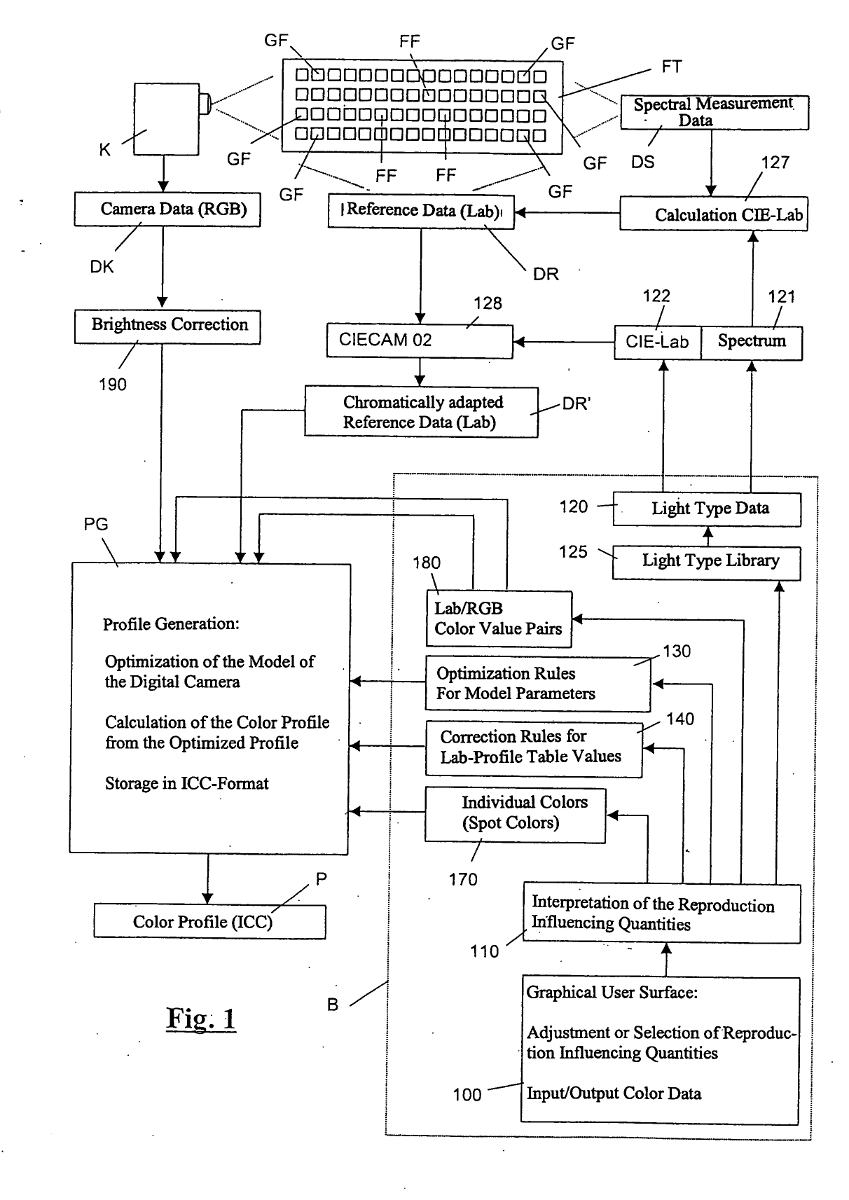

In contrast thereto, the profile generation is influenced in a different way in the profile generation process in accordance with the invention. On the one hand, one interferes for this in the profile generator or in the calculations taking place therein and, on the other hand, the calculated profile data are specifically changed. (Alternative to the change of the profile data, the reference data fed to the profile generator can also be correspondingly changed.) The process steps for these influencing measures are framed in FIG. 1 by the broken line box B. What occurs in detail and how is specifically described further below.

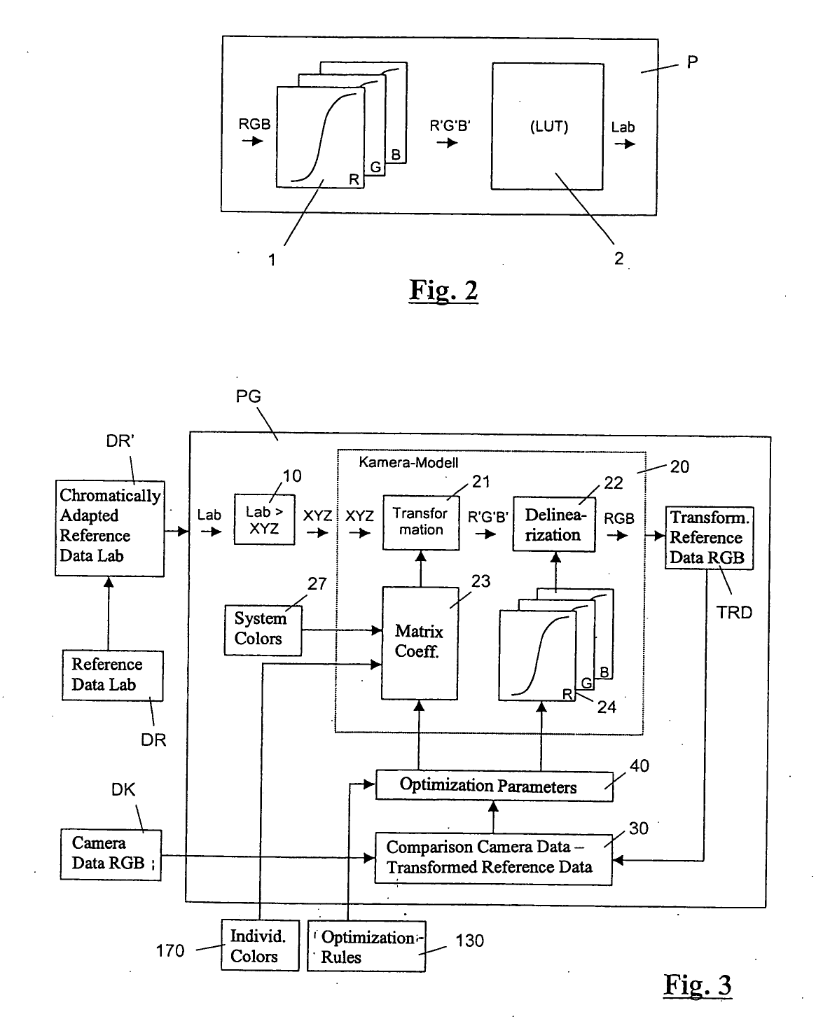

A profile for a digital camera describes, as already mentioned above, a clear transformation of device specific RGB-color values into the device independent Lab-color values (color coordinates). The principle structure of such a profile is illustrated in FIG. 2.

The profile P consists essentially of three linearization curves 1 (one curve per color channel RGB) and a conversion table 2 (“look up table”, LUT). By way of the linearization curves 1 (“tone reproduction curves”, TRC) a color management enabled application program processing the profile P can transfer the RGB-data into linearized R′G′B′-data. The curves 1 are implemented as supporting value tables with a series of input and output values so that intermediate values can be calculated by interpolation (for example linear). The conversion table 2 includes supporting values for a three-dimensional interpolation, by way of which the color management enabled application program can convert each sensible combination of (linearized) R′G′B′-color values into a matching combination of Lab-color values.

Therefore, the generation of a profile P includes in essence the calculation of the supporting values of the three linearization curves 1 and the supporting values of the conversion table 2 as well as the storage of the linearization curves and the conversion table in the standardized ICC-format. These calculations occur in the profile generator PG which is schematically illustrated in FIG. 3.

The profile generator PG includes in a generally known manner an Lab-XYZ-recalculation step 10, a common mathematical model 20 of a digital camera, as well as a comparison step 30 and a parameter optimization step 40. The camera model 20 consists of a transformation step 21 and a delinearization step 22 as well as a transformation table 23 and three delinearization curves 24 (one each per RGB-color channel).

The Lab-XYZ-recalculation step 10 recalculates the supplied Lab-reference data DR or chromatically adapted reference data DR′ according to the CIE-standards into corresponding XYZ-color values. The transformation table 23 includes the coefficients of a number of 3*3-transformation matrixes, by way of which the transformation step 21 recalculates the XYZ-color values by vector-matrix-multiplication into corresponding linearized R′G′B -color values. The XYZ-color space is thereby divided into several regions (color space regions), and for each region an individual 3*3-transformation matrix is provided. The color space regions are defined by a set of, for example, 10 system colors 27, which are essentially evenly distributed over the whole color space. The delinearization step 22 finally converts the linearized R′G′B′-color values by way of the delinearization curves 24 into the RGB-color values of the device dependent RGB-color space. The delinearization curves 24 are implemented as discrete value tables with a series of input and output values, so that intermediate values can be calculated by interpolation (for example linear). They correspond to delinearization curve 1 of the profile P, whereby however input and output are exchanged.

With the help of the camera model 20, the Lab-reference data DR or chromatically adapted Lab-reference data DR′ fed to the profile generator PG are recalculated into transformed (RGB-) reference data TRD. These transformed reference data TRD are compared in the comparison step 30 with the (RGB-) camera data DK also fed to the profile generator PG. The camera model 20 is now optimized by way of the parameter optimization step 40 through variations of its parameters, which means the matrix coefficients included in the transformation table 23 and the discrete values of the delinearization curves 24, starting from the experience-based starting values, until it transforms the Lab-reference data DR or the chromatically adapted Lab-reference data DR′ as exactly as possible into the RGB-camera data DK (comparison or error measure is normally the color distance). The common reproduction criteria (rendering intents) are thereby also taken into consideration.

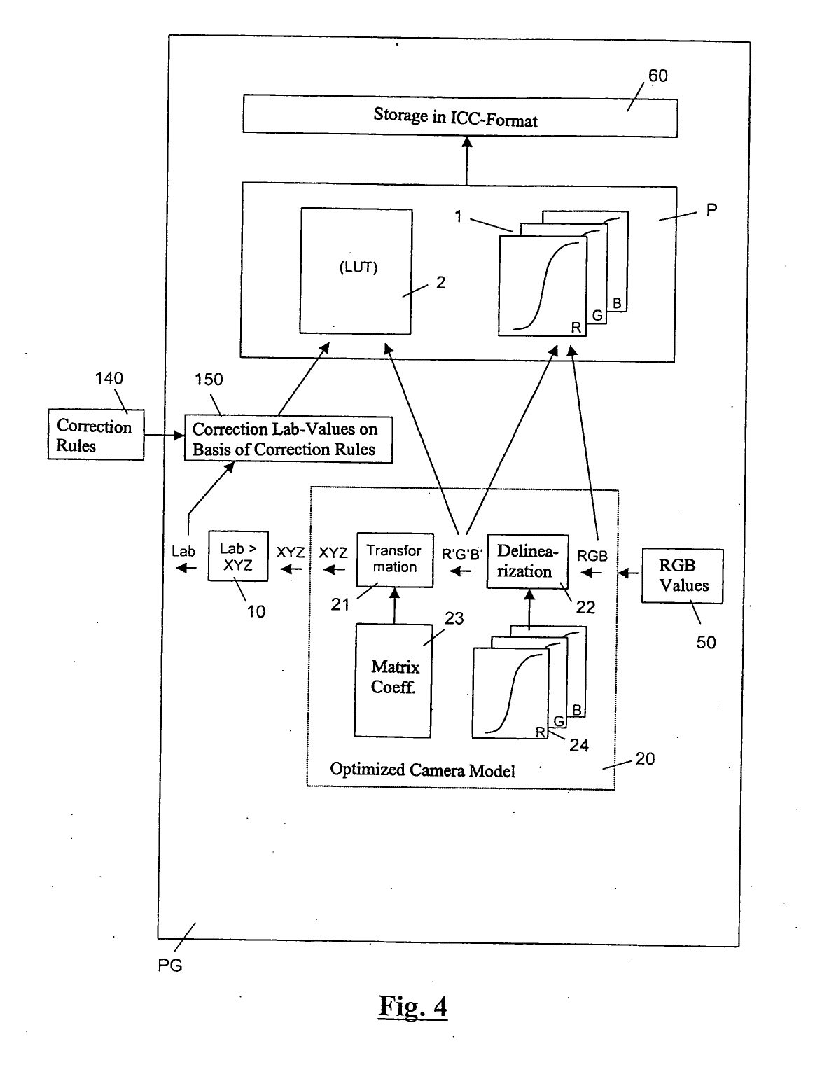

When the optimization of the camera model 20 is completed, the optimized model is used to calculate from a large number of RGB-color values the matching linearized R′G′B′ color values, the matching XYZ-color values and therefrom again the matching Lab-color values. For this, the model is operated in a generally known manner simply “in opposite direction” as illustrated in FIG. 4. From the data values calculated thereby one finally determines the profile P in a generally known manner as follows: the RGB-color values made available, for example, in a table 50, and the matching linearized R′G′B′-values form the discrete values for the three delinearization curves 1 of the profile P; the delinearized R′G′B′-color values and the three associated Lab-color values form the discrete values of the conversion table 2 of the profile P. The Lab-color values are according to the invention in a correction step 150 also corrected by way of correction values as will be more closely described further below. Finally, the data of the profile P are then stored in a data file in a storage step 60 in the standardized ICC format.

Apart from the correction step 150, the process in accordance with which the invention corresponds to the prior art so that the person skilled in the art does not require any further explanation.

The difference of the invention from the known prior art consists in that the user is offered the possibility to influence the profile calculation in many ways. According to an essential aspect of the invention, a graphic user interface or user surface is preferably made available therefor, which allows the input or change or selection of reproduction influencing quantities understandable to the user or known from the classic analogue photography. These reproduction influencing quantities adjusted or selected by the user are then incorporated into the profile calculation in form of corresponding calculation rules for the parameters (delinearization curves 24, matrix coefficients of the transformation table 23) of the mathematical camera model 20 and/or the corrections of the CIE-Lab color values in the transformation table 2 of the profile, whereby the user does not have to think about how and in which manner these adjustments or selections concretely enter into the profile calculation.

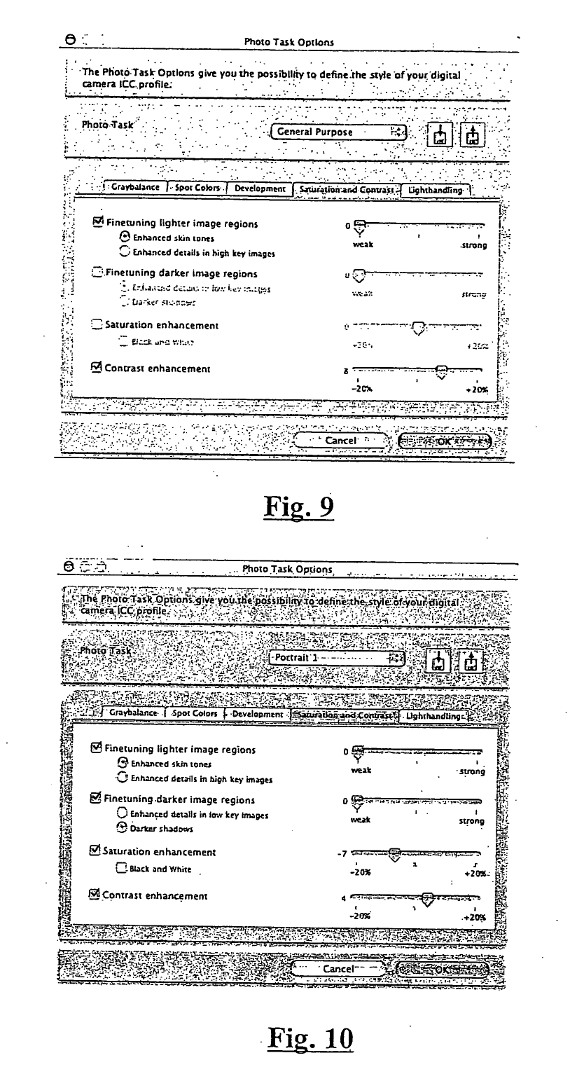

This is made clear in FIG. 1. In the user surface 100, different adjustments or selections still to be described can be made. These adjustments or selections are then evaluated in an interpretation step 110 and then determined in the form of light type data 120 and calculation rules 130 for the parameters (table values of the transformation table 23 and the delinearization curves 24) of the camera model 20 as well as the correction rules 140 for the Lab-color values in the transformation table 2 of the profile P and made available. The user surface 100 furthermore allows the input or selection of stored individual colors 170 as well as the input of additional Lab/RGB color value pairs 180. A suitable user surface typically has a menu structure and includes graphic input, output and adjustment elements with which the desired inputs, selections or adjustments can be made. An exemplary embodiment is shown in part in FIGS. 9 and 10. The programming technological realization of a suitable graphic user surface is generally known and therefore does not require any further explanation.

The most important input, selection and adjustment possibilities for user specific reproduction influence quantities according to the invention offered by the user surface 100 are described in the following. It is further described where and how these influence values act on the profile calculation.

A first possibility for interference consists in the selection of the light type with which the camera shots are to be made and for which the profile P to be generated is to be optimized. The emission spectra 121 of different typical light types are for this stored in a light type library 125 and can be selected by way of the user surface 100 and made available through the interpretation step 110 as light types 120. Additionally, the possibility can be offered to measure in a light type in a generally known manner by way of a spectrophotometer and to add the thereby obtained emission spectra to the light type library and/or directly make them available as selected light types 120.

The selected light types 120 are on the one hand, as far as the spectral data DS are present for the color fields FF of the color table ST, used in a calculation step 121 together with the spectral data DS for the calculation of the CIE-Lab-reference data DR. On the other hand, a chromatic adaptation of the CIE-Lab-reference data DR (by way of the underlying CIE-XYZ-data) is carried out in a generally known manner with the CIE-Lab-values 122 of the light type data 120 in the step 128 according to the color appearance model 01 of CIE (CIECAM 02), whereby the reference data DR are transferred into chromatically adapted reference data DR′. This chromatic adaptation can thereby be carried out completely or only partially (maintaining of the “light atmosphere”). For this, the user surface 100 offers an adjustment possibility which has an effect on the parameter D of the CIECAM 02-model (value 1.0 or 0.8).

According to a further important aspect of the invention, the camera data DK are before the feeding thereof into the profile generator PT subjected to a brightness correction 190, wherein potential unevenness of the capture (for example by uneven illumination of the color table) is compensated. For this purpose, a specially constructed color table FT is used which is equipped along its outer edges with several equal gray fields GF (white, gray, black). By way of the RGB-camera data from these special gray fields, possible unevenness can be easily recognized and then evened out by a corresponding increase or decrease of the RGB values of the actual color fields FF.

A further possibility for the influencing of the profile generation consists in the adjustment of the contrast, which means the strength of the brightness variation in relation to a change of the RGB-color values in the mean brightness region. The L-values of the CIE-Lab-color values calculated by way of the optimized camera model 20 are for this transferred into L′-values for the transformation table 2 of the profile P in the correction step 150 (FIG. 4) with a transformation function illustrated as graph in FIG. 6. As is apparent, the graph is slightly S-shaped and curved, whereby the end values (L=0 and L=100) and the mean value (L=50) are not changed. For a contrast enhancement, darker values (L<50) are attenuated and lighter values (L>50) are enhanced; for a contrast reduction, it is the opposite (curve 142′). The degree of reduction or increase (the slope of the transformation function 142 at the mean L=50), can be proportionally adjusted by the user by way of a corresponding adjustment element on the user surface 100 adjustable in contrast units. A switch is also provided by which the contrast influencing can be switched on or off. The transfer of the contrast units into corresponding mean point slope values for the transformation function 202 takes place in the interpretation step 110. The switch position and a mean point slope values form the correction roads regarding the contrast influencing which are then correspondingly transformed in the correction step 150.

The contrast adjustment can also be further improved in that a separate activation and adjustment possibility is provided (FIGS. 7 and 8) for bright (L>50) and dark (L<50) regions. A proper transformation function 143/143′ and 144/144′ is thereby used for each region which respectively only influences the brighter or darker L values (increases or lowers), but leaves the other L values unchanged. These transformation functions therefore graphically represent respectively the upper or lower half of the transformation function 142 or 142′, the other half is respectively linear with a slope of 1. The user surface 100 correspondingly offers separate activation switches and contrast adjustment elements for bright and dark regions. The switch positions and curve parameters together again form correction rules which are carried out in the correct step 150.

The transformation functions 142-144 or 142′-144′ illustrated in the FIGS. 6 to 8 as graphs are understood to be purely exemplary. The fixed points (L=L′) can also be selected differently in practice. Furthermore, the transformation functions are calculated in practice by way of supplying functions which use the adjustment values from the user surface 100 or the interpretation step 110 as parameters.

A further possibility for influencing consists in the adjustment (increase or decrease) of the color saturation. For an Lab-color value, one understands this to be the value s=(a²+b²)^{1/2}. At maximal unsaturation (a=0 and b=0) all colors become gray values. For this influencing, the a and b values of the Lab-color values calculated by way of the optimized camera model 20 are respectively multiplied with a factor f in the correction step 150 for the transformation table 2 of the profile P, so that
a′=f*a or b′=f*b
The factor f is calculated according to
f=(1+c*d/100)
wherein c is a value between −100 and +100 set by the adjustment of a corresponding adjustment element in the user surface 100 and d is a value depending on the color saturation s and the adjustment c, whereby for colors with color saturation s<50 and adjustment values c>0 the relation d=s/50 and in all other cases the relation d=1 applies. The adjustment value c or the factor calculated therefrom forms the correction rule regarding the color saturation correction, which is then carried out in the correction step 150.

A further possibility for the influencing consists in the behavior of the profile with respect to gray tones. The activation or gradual adjustment of this option provides that the profile to be generated carries out a more or less strong further reduction of the color saturation (only) for little saturated (which means almost gray) colors and depending on the adjustment. This is achieved in that the a and b values of the CIE-Lab-color values calculated by way of the optimized camera model 20 are multiplied with a factor g in the correction step 150 for the transformation table 2 of the profile P, so that
a′=g*a or b′=g*b

The factor g is the smaller, the smaller the a-value or b-value, and furthermore the smaller the L-value. It is calculated according to the formula
g=1.0/{1.0+(0.15+0.0085*e)/[0.5*(1.0+L/100)^{1/2})*(a²+b²)²]}

Wherein e is a value between 0 and 100 set by the adjustment of a corresponding adjustment element in the user surface 100. The adjustment value e or the factors g calculated therefrom form the correction rule regarding the gray tone behavior of the profile, which is then carried out in the correction step 150.

A further possibility of the influencing consists in the activation of a so called gray-balance-option. The gray-balance-option provides that the profile to be generated transforms “neutral” RGB-color values (R=B=G) into exact gray Lab-color values (a=b=0). This is realized in that during the optimization of the model 20 of the digital camera the parameter-optimization in the parameter-optimization step is influenced. Framework conditions for the variation (and thereby desired optimization) of the parameters are for this provided to the parameter optimization step 40 through the interpretation step 110 as a correction rule 130. Concretely, these framework conditions consist on one the hand in that the sums of the matrix coefficients 23 in the columns of each transformation matrix remain the same and on the other hand in that only one of the three linearization curves 24 is varied and the two others are set to be the same. The activation of the gray-balance-option again occurs by way of a corresponding switch element in the user surface 100.

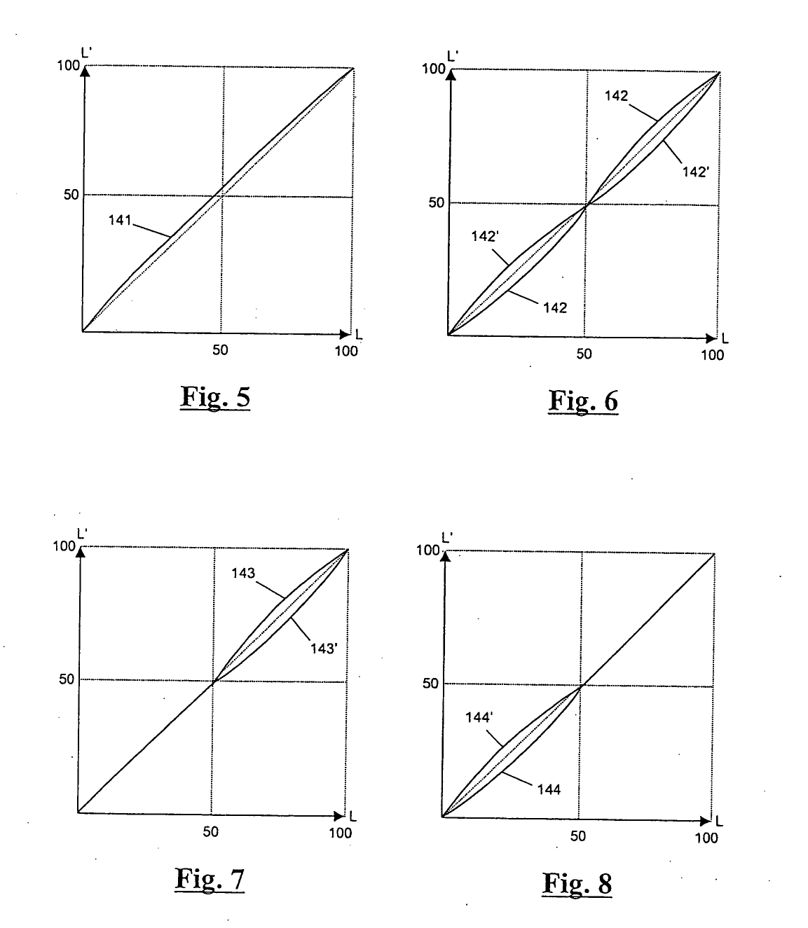

A further possibility for the influencing consists in the simulation of the so called “push-effect”. This is understood in the analog photography to be the targeted stepwise extension of the development process of the photographic material. In order to simulate the push-effect, the L values of the Lab-color values calculated by way of the optimized camera model 20 are transformed in the correction step 150 (FIG. 4) and with a transformation function, illustrated in FIG. 5 as a graph, into L′-values for the transformation table 2 of the profile P. As is apparent, the end values (L=0 and L=100) are thereby not changed, all intermediate L-values are increased, whereby the maximum increase is somewhat above the mean value (L=50). The activation of the push-effect (on/off) as well as the degree of increase can be adjusted by the user by way of a corresponding switch as well as a corresponding adjustment element in the user surface and changeable in push units. The transfer of the push units into corresponding degrees of increase for the adaptation of the transformation function 141 takes place in the interpretation step 110. The degree of increase and the activation condition represent the correction rule corresponding to the push-effect, by way of which the corresponding correction of the L-values is carried out in the correction step 150.

A further important possibility of influencing consists in the optimization of the profile with regard to its transformation properties for individual colors (“spot color optimization”).

As already mentioned further above, the camera model 20 includes the matrix coefficients 23 for a number of 3*3-tranformation matrixes, which are respectively valid for a color of a number of system colors distributed in the whole color space and are calculated during the optimization of the model. According to standard, about ten system colors and thereby separate transformation matrixes are used, whereby the system colors 27 are normally stored in a data file. According to an important aspect of the invention, further individual colors 170 (so called “spot colors”) can now be added on demand to this set of system colors, so that the total number of the colors for which separate transformation matrixes are calculated correspondingly increases. These individual colors are, for example, defined by their CIE-Lab-color values and can either be manually entered, read in from a suitable color file, or taken from a library of previously already stored individual colors, or possibly also measured in by way of a spectrophotometer. For this, the user surface 100 provides in a known manner suitable input or selection functions. During the optimization of the camera model 20 a proper 3*3 transformation matrix is now calculated for each of these individual colors 170 in addition to the system colors 27 and in such a way that the model fits best for those colors or color fields SF of the color table FT which are respectively closest to the individual color 170. This occurs in that each color in the color table (represented by the corresponding CIE-Lab reference data DR) is assigned a weight G, which decreases with increasing color distance (ΔE) from the corresponding individual color 170. During the optimization of the model 20 to the colors of the color table FT, the error of the model for each color of the color table FT is multiplied with the weight of the corresponding color so that the error of colors in the vicinity of the individual colors 170 is more strongly taken into consideration. This leads to the optimized transformation matrixes fitting best for those colors which are similar (or equal) to the individual colors 170.

After this optimization, the model 20 includes all those matrixes which respectively are optimal for one region (defined by the system color 27 and individual colors 170) in the color space. During the subsequent use of the model 20 for the calculation of the profile table values (discrete values of the transformation table 2 of the profile P, compare FIG. 4) the coefficients of all 3*3-matrixes are provided with a weight and weighted averaged to a single 3*3 matrix. The weights calculate from the color distance of the color respectively to be calculated from the individual color for which the matrix was optimized, whereby the weights are selected smaller with increasing color distance.

A further possibility of influencing consists finally in that the precision of the profile to be generated is still increased for single individual colors in that the color table FT is virtually expanded, which means in addition to the CIE-Lab-reference data and RGB-camera data of the color table FT further CIE-Lab/RGB-color value pairs 180 (CIE-Lab-color values and corresponding RGB-camera data) are used for the profile generation. These color value pairs can, for example, be entered manually through the user surface 100. Preferably, the CIE-Lab-color values of these color value pairs are added to the system colors 27 as individual colors 170 to be optimized, as described above under “spot color optimization” and integrated into the profile generation.

According to a further important aspect of the invention, the above described possibilities of influencing the profile generation are now combined into sensible combinations and offered to the user by way of the user surface 100, thematically sorted and under content-strong and easily understandable titles. Pre-settings are thereby offered for typical applications or situations, whereby the user however has the possibility to still change these pre-settings according to individual requirements and furthermore the possibility to store the changed settings for later reuse.

A superior thematic grouping includes, for example, the following points: Scene light: adjustment/selection of a light type Photo tasks or use purpose of the profile.

A further organization or grouping occurs according to the typical photographic tasks or use purpose of the profile (P) to be generated. Examples for predefined photo tasks or use purposes are such as portrait, landscape, product etc.

An additional grouping of the reproduction influencing quantities or influencing possibilities can also be made according to the properties of the transformation behavior of the profile (P) to be generated which they influence. The individual photo tasks can be grouped, for example, according to the following themes:
Gray-Balance: gray balance and neutralization of near gray colors
Special colors: spot colors and color table expansion
Development: push-effect simulation
Saturation/contrast: all adjustment possibilities regarding color saturation and contrast
Scene light: adjustment of the chromatic adaptation

A set of parameters is stored for each photo task which fixes for the respective photo task the pre-settings of the selection and adjustment possibilities for the reproduction influencing quantities which are best according to experience. Upon selection of a photo task in the graphic user surface 100, the associate parameter set is loaded and the selection and adjustment elements of the user surface correspondingly initialized. FIGS. 9 and 10 illustrate this purely exemplary.

In FIG. 9, the user is in the category “photo task” (“Photo Task Options”) and has selected therein the predefined task “general purpose”; he also wants to generate an all purpose camera profile. Under the theme “saturation and contrast” (“Saturation and Contrast”) he is offered the following presettings:

The contract fine adjustment of lighter colors (“fine tuning lighter image sections”) is activated, whereby skin tones are slightly enhanced (“Enhanced Skin Tones”). This corresponds to a weakly adjusted correction according the curve 143 in FIG. 7. The contrast fine tuning of darker colors (“fine tuning darker image sections”) is deactivated according to FIG. 8. The general contrast enhancement (“Contrast Enhancement”) is activated and adjusted to 8% (curve 142 in FIG. 6). The correction of the color saturation (“Saturation Enhancement”) is deactivated.

In FIG. 10, the user is also in the category “Photo Tasks” and has selected therein the predefined task “Portrait 1”; he also wants to generate a camera profile optimized especially for portrait shots. Under the theme “Saturation and Contrast” he is offered this time the following pre-settings:

The contrast fine tuning of lighter colors is activated, whereby skin tones are weakly enhanced. This corresponds to a weakly adjusted correction according to the curve 143 in FIG. 7. The contrast fine tuning of darker colors is also activated, whereby darker shadow regions (“darker shadows”) are weakly enhanced. This corresponds to a weakly enhanced correction according to curve 144′ in FIG. 8. The general contrast enhancement is activated and adjusted to 4% (curve 142 in FIG. 6). The correction of the color saturation is activated and adjusted to 7% reduction. (The activation of the option “Black and White” would cause a total unsaturation of the colors and thus would lead to a black and while image with the use of this profile.)

Analogously, suitable pre-settings are also made for the remaining themes (“Gray-Balance”, “Spot Colors”, “Development”, “Light Handling”).

The user can now take over these pre-settings or, as already mentioned, change them according to his personal desires. The possibility is thereby also offered to store the changed selections or adjustments under the same or a different name for the photo task. When storing under the same name, the associated parameter set is changed, while when storing under a new name a new parameter set is built.

By grouping the possibilities of influencing according to typical application situations or photographic tasks and combining related possibilities of influencing and labeling them with terms familiar to the user, the practical use of the process in accordance with the invention is much facilitated. With the process of the invention, the user can carry out in a simple and intuitive manner perception based and individual taste based aspects of the color reproduction as well as influencing measures of the color reproduction known from the classical analog photography, and can let them flow into the profile generation.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

1. Process for the generation of a color profile for a digital camera using reference data (DR) and camera data and a mathematical model of the digital camera defined by variable parameters, whereby the reference data (DR) represent color values of color fields of a color table (FT) in relation to a device independent color space and the camera data (DK) represent color values of the color fields of the color table produced by the digital camera upon capture of the color table in relation to a device specific color space of the digital camera, and the model of the digital cameral transforms color values relating to the device independent color space into color values of the device specific color space of the digital camera, whereby the reference data (DR) are transformed by way of the model of the digital camera into the device specific color space of the digital camera, comprising the steps of
providing a user surface for input, adjustment, or selection of reproduction influencing quantities characterizing a transformation behavior of a color profile (P) to be generated;
determining from the input, adjusted, or selected reproduction influencing quantities at least one of corresponding optimization rules for optimization of the parameters of the model of the digital camera and corresponding correction rules for table values of the color profile (P);
optimizing the model of the digital camera by variation of its parameters so that transformed reference data (TRD) correspond, under consideration of reproduction criteria, to the camera data (DK), optimization of the parameters of the model of the digital camera being carried out by way of the optimization rules and the table values of the color profile (P) being changed according to the correction rules; and
forming the color profile (P) by way of the optimized model of the digital camera.

2. Process according to claim 1, wherein the user surface presents different reproduction quantities combined into thematic groups and offered to the user with experience based pre-settings for selection or individual adjustment.

3. Process according to claim 2, wherein the reproduction influencing quantities are grouped according to typical photographic tasks or use purposes of the color profile (P) to be generated.

4. Process according to claim 1, wherein the user surface presents different reproduction influencing quantities grouped according to properties of the transformation behavior of the profile (P) which they influence.

5. Process according to claim 1, wherein the camera data (DK) of the color table (FT) are subjected to a brightness correction which compensates unevenness during capture of the color table with the digital camera.

6. Process according to claim 5, wherein the color table (FT) used includes at its outer borders multiple gray fields (GF), and the brightness correction is carried out based on the camera data (DK) stemming from gray fields (GF).

7. Process according to claim 1, wherein a contrast behavior of the profile (P) is adjusted for an overall contrast strengthening or contrast reduction.

8. Process according to claim 1, wherein a contrast behavior of the profile (P) is separately adjusted for an upper and a lower brightness region for a contrast strengthening or contrast reduction.

9. Process according to claim 1, wherein a color saturation behavior of the profile (P) is adjusted for saturation strengthening or saturation reduction.

10. Process according to claim 1, wherein a behavior of the profile (P) is adjusted with respect to colors lying close to gray in such a way that the color profile causes a reduction in color saturation of such colors.

11. Process according to claim 1, wherein a gray balance behavior of the profile (P) is adjusted in such a way that the color profile transforms neutral colors into exact gray tones.

12. Process according to claim 1, wherein a push-effect is adjusted which influences a behavior of the profile (P) in such a way that it causes a brightness increase in a mean brightness region.

13. Process according to claim 1, wherein a light type is adjusted and the color profile (P) optimized for the adjusted light type.

14. Process according to claim 1, wherein the reference data (DR) are chromatically adapted to an adjusted light type, whereby a degree of adaptation is adjusted.

15. Process according to claim 1, wherein at least one special color not included in the color table (FT) is used for optimization of the model of the digital camera.

16. Process according to claim 1, wherein at least one RGB/CIE-Lab color value pair not originating from the color table (FT) is used for optimization of the model of the digital camera.

17. Process according to claim 1, wherein the user surface is a graphic user surface.
